(19) United States
(12) Patent Application Publication
(10) Pub. No.: US 2004/0263465 A1
(43) Pub. Date: Dec. 30, 2004

(54) Display

(75) Inventor: Koji Hirosawa, Ichinomiya-shi (JP)

Correspondence Address: McDERMOTT, WILL & EMERY, 600 13th Street, N.W., Washington, DC, 20005-3096, US

(73) Assignee: SANYO ELECTRIC CO., LTD.

(21) Appl. No.: 10/811,880

(22) Filed: Mar. 30, 2004

(30) Foreign Application Priority Data
Jun. 30, 2003 (JP) JP2003-186036

(51) Int. Cl. G09G 3/36

(52) U.S. Cl. 345/100

(57) ABSTRACT

A display capable of suppressing the current consumption is disclosed. The display comprises a plurality of stages of shift register circuits for sequentially driving a plurality of drain lines and a plurality of stages of first dummy shift register circuits arranged on the operation starting side of the plurality of stages of shift register circuits and not connected to the drain lines. The first dummy shift register circuits include a first transistor connected to a first potential, a second transistor connected to a second potential, and a third transistor for turning off the first transistor when the second transistor is in on state.

### BACKGROUND OF THE INVENTION

1. Field of the Invention

The present invention relates to a display, or in particular to a display having shift register circuits.

2. Description of the Related Art

A conventional inverter circuit of resistance load type having a load resistance is known. This inverter circuit is disclosed, for example, in Seigo Kishino: “Basis of Semiconductor Device” published by Ohmsha, Ltd., pp.184-187, Apr. 25, 1985.

Also, a conventional shift register circuit having an inverter circuit of resistance load type is known. The shift register circuit is used with a circuit for driving the gate line and the drain line of, for example, a liquid crystal display and an organic EL display. FIG. 13 is a circuit diagram of the conventional shift register circuit having an inverter circuit of resistance load type. The conventional first-stage shift register circuit 104a1 shown in FIG. 13 is configured of a first circuit section 104b1 and a second circuit section 104c1. The shift register circuit 104a2 in the stage following the shift register circuit 104a1 is configured of a first circuit section 104b2 and a second circuit section 104c2.

The first circuit section 104b1 includes n-channel transistors NT101 and NT102, a capacitor C101 and a resistor R101. In the description of the prior art that follows, the n-channel transistors NT101, NT102 and NT103 are referred to simply as the transistors NT101, NT102 and NT103, respectively. The drain of the transistor NT101 is supplied with a start signal ST, and the source thereof is connected to a node ND101. The gate of the transistor NT101 is connected to a CLK1 of the clock signal line. Also, the source of the transistor NT102 is connected to the negative potential (VSS), and the drain thereof is connected to a node ND102. Further, one of the electrodes of the capacitor C101 is connected to the negative potential (VSS), and the other electrode thereof is connected to the node ND101. A resistor R101 is interposed between the node ND102 and the positive potential (VDD). The transistor NT102 and the resistor R101 make up an inverter circuit.

The second circuit section 104c1 of the first-stage shift register circuit 104a1 is configured of an inverter circuit including a transistor NT103 and a resistor R102. The source of the transistor NT103 is connected to the negative potential (VSS), while the drain thereof is connected to the node ND103. The gate of the transistor NT103 is connected to the node ND102 of the first circuit section 104b1. A resistor R102 is interposed between the node ND103 and the positive potential (VDD). An output signal SR1 of the first-stage shift register circuit 104a1 is output from the node ND103. The node ND103 is connected with the first circuit section 104b2 of the second-stage shift register circuit 104a2.

The shift register circuits in the second and subsequent stages are also configured similarly to the first-stage shift register circuit 104a1. The first circuit section of the shift register circuit in a given stage is connected to the output node of the shift register circuit in the preceding stage.

FIG. 14 is a timing chart of the conventional shift register circuit shown in FIG. 13. Next, with reference to FIGS. 13 and 14, the operation of the conventional shift register circuit is explained.

First, an L-level start signal ST is input as an initial mode. After the start signal ST is raised to H level, the clock signal CLK1 is raised to H level. As a result, the gate of the transistor NT101 of the first circuit section 104b1 of the first-stage shift register circuit 104a1 is supplied with the H-level clock signal CLK1, thereby turning on the transistor NT101. Thus, the H-level start signal ST is supplied to the gate of the transistor NT102 thereby to turn on the transistor NT102. The potential of the node ND102 is then reduced to L level, and therefore the transistor NT103 is turned off. The potential of the node ND103 increases so that a H-level signal is output as an output signal SR1 from the first-stage shift register circuit 104a1. This H-level signal is supplied also to the first circuit section 104b2 of the second-stage shift register circuit 104a2. By the way, the H-level potential is stored in the capacitor C101 as long as the clock signal CLK1 is at H level.

Next, the clock signal CLK1 is reduced to L level. As a result, the transistor NT101 is turned off. After that the start signal ST is reduced to L level. In the process, even though the transistor NT101 turns off, the potential of the node ND101 is held at H level by the H-level potential stored in the capacitor C101, and therefore the transistor NT102 is kept on. Since the potential of the node ND102 is held at L level, the gate potential of the transistor NT103 is held at L level. As a result, the transistor NT103 is kept off, and therefore, an H-level signal continues to be output as an output signal SR1 from the second circuit section 104c1.

The clock signal CLK2 input to the first circuit section 104b2 of the second-stage shift register circuit 104a2 is raised to H level. In the second-stage shift register circuit 104a2, therefore, the H-level clock signal CLK2 is input with the H-level output signal SR1 input from the first-stage shift register circuit 104a1. Thus, the operation similar to the first-stage shift register circuit 104a1 is performed. As a result, a H-level output signal SR2 is output from the second circuit section 104c2.

After that, the clock signal CLK1 is raised again to H level. The transistor NT101 of the first circuit section 104b1 is turned on. In the process, the potential of the node ND101 drops to L level since the start signal ST is at L level. The transistor NT102 is turned off, and therefore the potential of the node ND102 is raised to H level. As a result, the transistor NT103 is turned on, and the potential of the node ND103 is reduced to L level from H level. An L-level output signal SR1 is output from the second circuit section 104c1. By the operation described above, H-level output signals (SR1, SR2, SR3 and so forth) shifted in timing are sequentially output from the shift register circuits in the respective stages.

In the first-stage shift register circuit 104a1 of the conventional shift register circuit shown in FIG. 13, however, during the H-level period of the output signal SR1, the transistor NT102 is held on, and therefore, a penetration current inconveniently flows between the positive potential VDD and the negative potential VSS through the resistor R101 and the transistor NT102. Also, during the L-level period of the output signal SR1, the transistor NT103 is held on, and therefore, the penetration current flows inconveniently between the positive potential VDD and the negative potential VSS through the resistor R102 and the transistor NT103. Therefore, regardless of whether the output signal SR1 is at H level or L level, the penetration current inconveniently flows always between the positive potential VDD and the negative potential VSS. The shift register circuits in other stages also have a similar configuration to the first-stage shift register circuit 104a1. Like the first-stage shift register circuit 104a1, therefore, the penetration current inconveniently flows always between the positive potential VDD and the negative potential VSS regardless of whether the output signal is at H or L level. As a result, in the case where the conventional shift register circuit described above is used as a circuit for driving the gate line or the drain line of a liquid crystal display or an organic EL display, the problem is posed that the current consumption of the liquid crystal display or the organic EL display, as the case may be, increases.

### SUMMARY OF THE INVENTION

The object of this invention is to provide a display capable of suppressing the increase in current consumption.

In order to achieve the object described above, according to a first aspect of the invention, there is provided a display comprising a plurality of stages of shift register circuits for sequentially driving a plurality of drain lines for supplying a video signal to pixels, and a plurality of stages of first dummy shift register circuits arranged on the operation starting side of the plurality of stages of shift register circuits and not connected to the drain lines, wherein the shift register circuits and the first dummy shift register circuits include a first circuit section having a first transistor of first conductivity type connected to the first potential, a second transistor of first conductivity type connected to the second potential and a third transistor of first conductivity type connected between the gate of the first transistor and the second potential for turning off the first transistor when the second transistor is in on state.

In the display according to the first aspect of the invention, the first transistor connected to the first potential and the second transistor connected to the second potential are prevented from turning on at the same time, and therefore the penetration current is prevented from flowing between the first potential and the second potential through the first and second transistors in the first circuit section. Also, in the case where a display is fabricated by connecting the shift register circuits described above in a plurality of stages and connecting the plurality of stages of shift register circuits to the pixels constituting a display section, display irregularities may occur in an area corresponding to the drain line connected to the second-stage one, from the operation start side, of the plurality of stages of shift register circuits of the display section. In view of this, according to this first aspect of the invention, as described above, a plurality of stages of first dummy shift register circuits not connected to the drain lines are arranged on the operation starting side of the plurality of stages of the shift register circuits. In this way, the second-stage shift register circuit from the operation start side constitutes the first dummy shift register circuit not connected to the drain lines, and therefore the display irregularities are prevented from being generated in an area corresponding to the second-stage shift register circuit from the operation start side.

According to a second aspect of the invention, there is provided a display comprising a plurality of stages of shift register circuits for sequentially driving a plurality of drain lines for supplying the video signal to pixels, and at least a plurality of stages of dummy shift register circuits arranged on side opposite to the operation start side of the plurality of the shift register circuits and not connected to the drain lines, wherein the shift register circuits and the dummy shift register circuits include a first circuit section having a first transistor of first conductivity type connected to the first potential, a second transistor of first conductivity type connected to the second potential and a third transistor of first conductivity type connected between the gate of the first transistor and the second potential for turning off the first transistor when the second transistor is in on state.

In the display according to the second aspect of the invention, the first transistor connected to the first potential and the second transistor connected to the second potential are prevented from turning on at the same time. In the first circuit section, therefore, the penetration current is prevented from flowing between the first potential and the second potential through the first and second transistors. Also, in the case where a display is fabricated by connecting the shift register circuits described above in a plurality of stages and connecting the plurality of stages of shift register circuits to the pixels constituting the display section, display irregularities may occur in an area corresponding to the drain line connected to the first-stage (last-stage) shift register circuit opposite to the operation start side of the plurality of stages of shift register circuits of the display section. In view of this, according to this second aspect of the invention, as described above, a dummy shift register circuit not connected to the drain line is arranged at least on the side opposed to the operation start side of the plurality stages of shift register circuits. In this way, the last-stage shift register circuit constitutes a dummy shift register circuit not connected to the drain lines, and therefore the display irregularities are prevented from being generated in an area corresponding to the last-stage shift register circuit.

### BRIEF DESCRIPTION OF THE DRAWINGS

FIG. 1 is a plan view showing a liquid crystal display according to a first embodiment of the invention;

FIG. 2 is a circuit diagram showing a shift register circuit constituting an H driver of the liquid crystal display according to the first embodiment shown in FIG. 1;

FIG. 3 is a circuit diagram showing the last stage of the shift register circuit shown in FIG. 2;

FIG. 4 is a schematic diagram for explaining the structure of a p-channel transistor having two gate electrodes;

FIG. 5 is a timing chart of a shift register circuit for the H driver of the liquid crystal display according to the first embodiment shown in FIG. 1;

FIG. 6 is a circuit diagram of a shift register circuit constituting the H driver of the liquid crystal display according to a second embodiment of the invention;

FIG. 7 is a circuit diagram showing the last stage of the shift register circuit shown in FIG. 6;

FIG. 8 is a timing chart of the shift register circuit for the H driver of the liquid crystal display according to the second embodiment shown in FIG. 6;

FIG. 9 is a circuit diagram of the shift register circuit constituting the H driver of the liquid crystal display according to a third embodiment of the invention;

FIG. 10 is a circuit diagram showing the last stage of the shift register circuit shown in FIG. 9;

FIG. 11 is a timing chart of the shift register circuit for the H driver of the liquid crystal display according to the third embodiment shown in FIG. 9;

FIG. 12 is a plan view showing an organic EL display according to a fourth embodiment of the invention;

FIG. 13 is a circuit diagram showing a conventional shift register circuit having an inverter circuit of resistance load type; and

FIG. 14 is a timing chart of the conventional shift register circuit shown in FIG. 13.

### DESCRIPTION OF THE PREFERRED EMBODIMENTS

Embodiments of this invention are described below with reference to the accompanying drawings.

First Embodiment

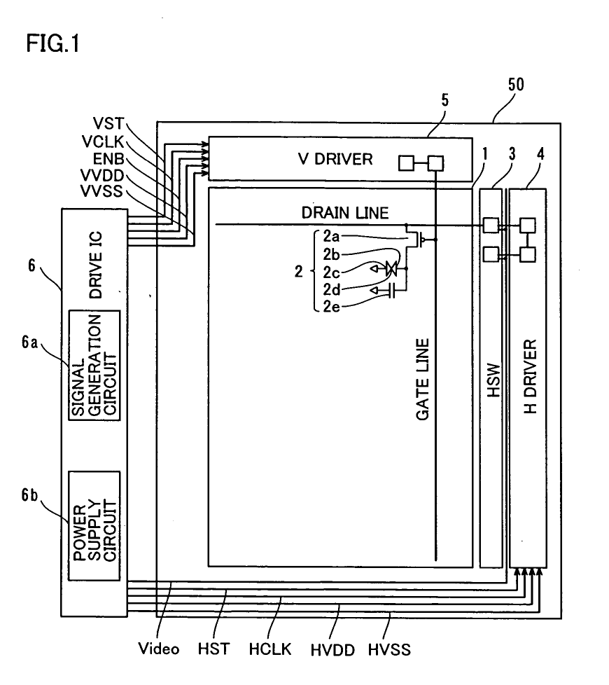

According to a first embodiment of the invention shown in FIG. 1, a display section 1 is arranged on a board 50. The display section 1 shown in FIG. 1 represents a configuration having one pixel. In the display section 1, pixels 2 are arranged in matrix. Each pixel 2 is configured of a p-channel transistor 2a, a pixel electrode 2b, an opposite electrode 2c arranged in opposed relation to the pixel electrode 2b and shared by the pixels 2, a liquid crystal 2d held between the pixel electrode 2b and the opposite electrode 2c, and an auxiliary capacitor 2e. The gate of the p-channel transistor 2a is connected to the gate line. The source of the p-channel transistor 2a is connected to the drain line. The drain of the p-channel transistor 2a is connected with the pixel electrode 2b and the auxiliary capacitor 2c.

Along one side of the display section 1, a horizontal switch (HSW) 3 and an H driver 4 for driving (scanning) the drain line of the display section 1 are arranged on the board 50. Also, along the other side of the display section 1, a V driver 5 for driving (scanning) the gate line of the display section 1 is arranged on the board 50. In FIG. 1, although only two horizontal switches HSW are shown, as many horizontal switches HSW as the pixels are actually arranged. Also, in spite of the fact that only two shift registers are shown for the H driver 4 and the V driver 5, as many shift registers as the pixels are actually arranged. A drive IC 6 is arranged outside of the board 50. This drive IC 6 includes a signal generation circuit 6a and a power supply circuit 6b. A start signal HST, a clock signal HCLK, a positive potential HVDD and a negative potential HVSS are supplied from the drive IC 6 to the H driver 4. Also, a start signal VST, a clock signal VCLK, an enable signal ENB, a positive potential VVDD and a negative potential VVSS are supplied from the drive IC 6 to the V driver 5.

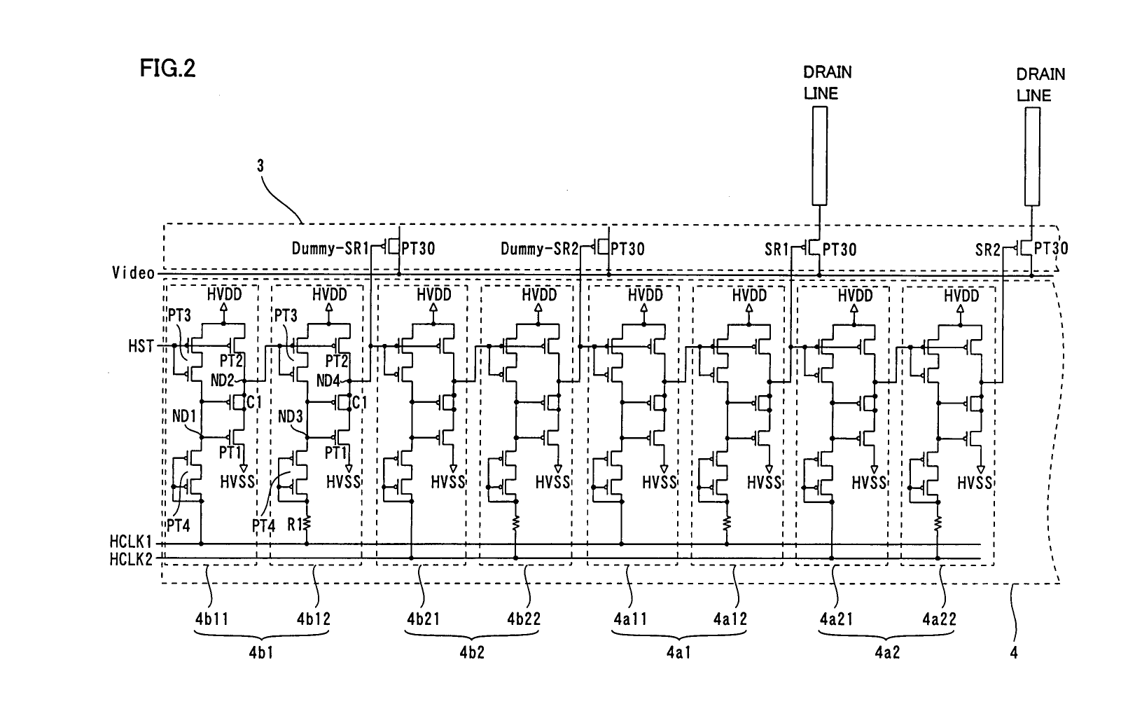

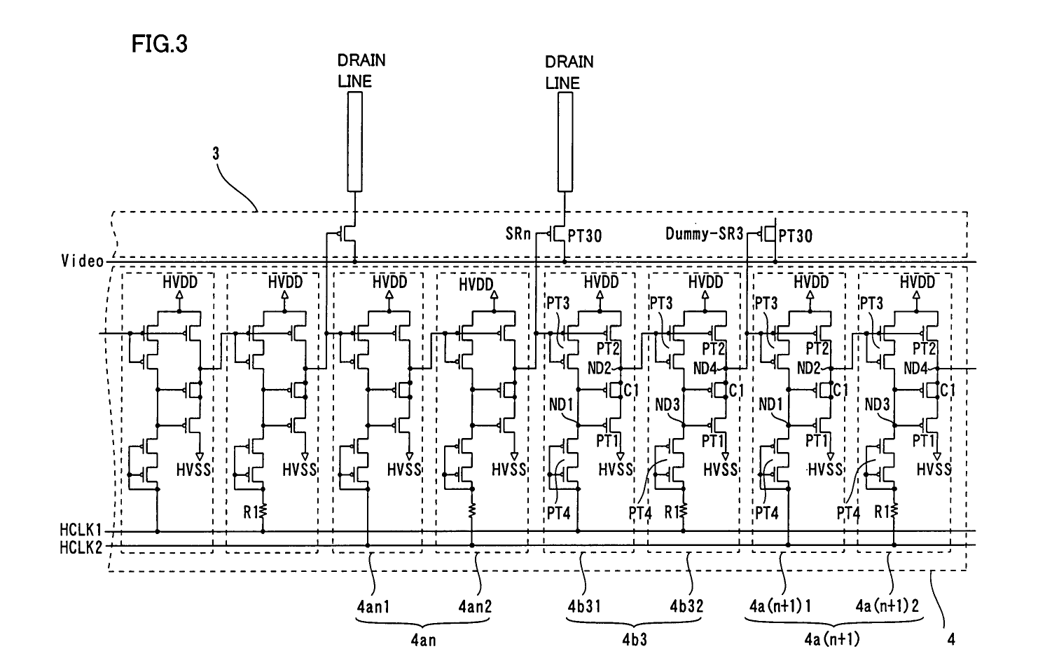

As shown in FIGS. 2 and 3, the H driver 4 includes a plurality of shift register circuits 4a1, 4a2, . . . , 4an connected to the drain line.

According to this first embodiment, two stages of dummy shift register circuits 4b1, 4b2 not connected to the drain line are included in the stage before the shift register circuits 4a1, 4a2, . . . , 4an not connected to the drain line. Also, according to this first embodiment, as shown in FIG. 3, a dummy shift register circuit 4b3 is arranged in the stage following the last stage of the shift register circuits 4a1, 4a2, . . . , 4an connected to the drain line. A shift register circuit 4a(n+1) not connected to the horizontal switch is arranged in the stage following the dummy shift register circuit 4b3. The dummy shift register circuits 4b1, 4b2 are an example of “the first dummy shift register circuit” according to the invention. Also, the dummy shift register circuit 4b3 is an example of “the second dummy shift register circuit” according to the invention.

According to this first embodiment, as shown in FIG. 2, the start signal HST is input to the dummy shift register circuit 4b1 in the first stage (initial stage). As a result, as compared with the case lacking the two stages of the dummy shift register circuits 4b1, 4b2, the position of the shift register circuits supplied with the start signal can be displaced by two stages forward, and therefore the timing of inputting the start signal HST can be advanced by two clocks.

The first-stage dummy shift register circuit 4b1 is configured of the first circuit section 4b11 and the second circuit section 4b12. The first circuit section 4b11 and the second circuit section 4b12 are an example of “the first circuit section” according to the invention, and include p-channel transistors PT1, PT2, PT3, a diode-connected p-channel transistor PT4, and a capacitor C1 formed by connecting the source and the drain of the p-channel transistors. The p-channel transistors PT1, PT2, PT3, PT4 are an example of the “first transistor”, “the second transistor”, “the third transistor” and “the fourth transistor”, respectively, according to this invention. The capacitor C1 is an example of “the first capacitor” according to the invention. The second circuit section 4b12, unlike the first circuit section 4b11, further includes a high resistor R1.

According to the first embodiment, the p-channel transistors PT1 to PT4 included in the first circuit section 4b11 and the second circuit section 4b12 and the p-channel transistor making up the capacitor C1 are all configured of a TFT (thin film transistor) formed of a p-type MOS transistor (field effect transistor). The p-channel transistors PT1 to PT4 are hereinafter referred to as the transistors PT1 to PT4, respectively.

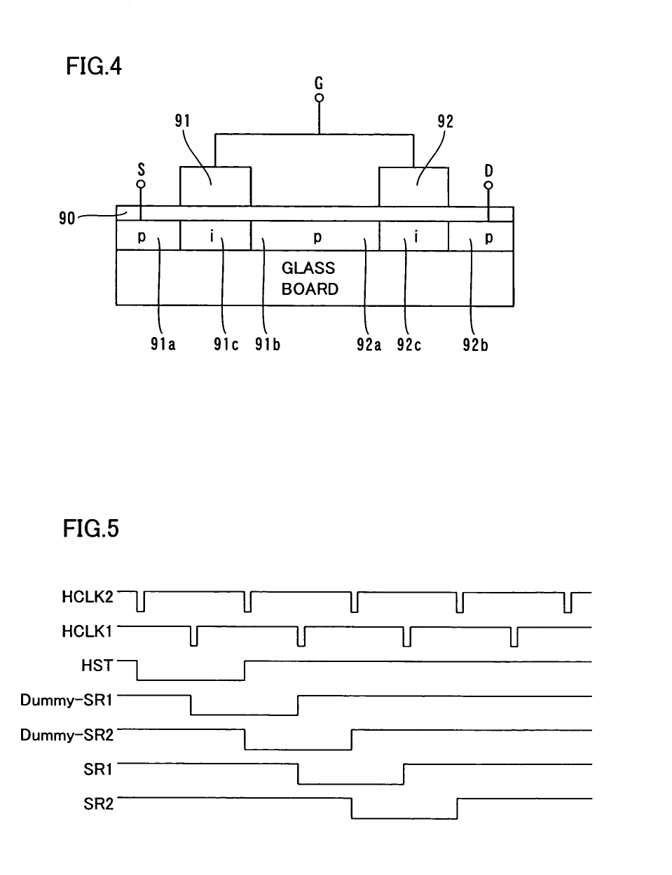

Also, according to this first embodiment, the transistors PT3 and PT4 are formed to have two gate electrodes 91 and 92 electrically connected to each other, as shown in FIG. 4. Specifically, the gate electrode 91 and the gate electrode 92 are formed on a channel region 91c and a channel region 92c, respectively, through a gate insulating film 90. The channel region 91c is formed in such a manner as to be held between the source region 91a and the drain region 91b, while the channel region 92c is formed in such a manner as to be held between the source region 92a and the drain region 92b. Also, the drain region 91b and the source region 92a are configured of a common impurity region.

As shown in FIG. 2, in the first circuit section 4b11, the source of the transistor PT1 is connected to the node ND2, and the drain thereof is connected to the negative potential HVSS. The negative potential HVSS is an example of “the first potential” according to the invention. The gate of the transistor PT1 is connected to the node ND1 and supplied with the clock signal HCLK1. The source of the transistor PT2 is connected to the positive potential HVDD, and the drain thereof is connected to the node ND2. The positive potential HVDD is an example of “the second potential” according to this invention. The gate of the transistor PT2 is supplied with the start signal HST.

According to the first embodiment, the transistor PT3 is connected between the gate of the transistor PT1 and the positive potential HVDD. The gate of the transistor PT3 is supplied with the start signal HST. The transistor PT3 is operated to turn off the transistor P1 when the transistor PT2 is on. As a result, both the transistor PT2 and the transistor PT1 are prevented from turning on at the same time.

According to the first embodiment, the capacitor C1 is interposed between the gate and the source of the transistor PT1. The diode-connected transistor PT4 is interposed between the gate of the transistor PT1 and the clock signal line HCLK1. The diode-connected transistor PT4 suppresses the H-level pulse voltage of the clock signal line HCLK1 from flowing reversely from the clock signal line HCLK1 to the capacitor C1.

The circuit configuration of the second circuit section 4b12 is basically similar to that of the first circuit section 4b11. In the second circuit section 4b12, however, the source of the transistor PT1 and the drain of the transistor PT2 are connected to the node ND4, respectively, while the gate of the transistor PT1 is connected to the node ND3. Also, the high resistor R1 is interposed between the transistor PT4 and the clock signal line HCLK1.

An output signal Dummy-SR1 of the first-stage dummy shift register circuit 4b1 is output from the node ND4 (output node) of the second circuit section 4b12. The node ND4 (output node) of the first-stage dummy shift register circuit 4b1 is connected with the second-stage dummy shift register circuit 4b2.

The second-stage dummy shift register circuit 4b2, the shift register circuits 4a1, 4a2, . . . , 4an, 4a(n+1) in a plurality of stages and the dummy shift register circuit 4b3 in the last stage also have a circuit configuration similar to that of the first-stage dummy shift register circuit 4b1. Specifically, the second-stage dummy shift register circuit 4b2 and the last-stage dummy shift register circuit 4b3 are configured of the first circuit sections 4b21, 4b31 and the second circuit sections 4b22, 4b32, respectively, having a similar configuration to the first circuit section 4b11 and the second circuit section 4b12 of the first-stage dummy shift register circuit 4b1. Also, the shift register circuits 4a1, 4a2, . . . , 4an, 4a(n+1) in a plurality of stages are configured of the first circuit sections 4a11, 4a21, . . . , 4an1, 4a(n+1)1 and the second circuit sections 4a12, 4a22, . . . , 4an2, 4a(n+1)2, respectively, having a similar configuration to the first circuit section 4b11 and the second circuit section 4b12 of the first-stage dummy shift register circuit 4b1. By the way, the first circuit section of the shift register circuit in a given stage is connected to the output node of the shift register circuit in the preceding stage.

As shown in FIGS. 2 and 3, the horizontal switch 3 has a transistor PT30 in each stage. The gate of the transistor PT30 in each stage is connected to the node ND4 providing an output node of each stage. As a result, the transistor PT30 of each stage is supplied with the output signal (Dummy-SR1, Dummy-SR2, SR1, SR2, . . . , SRn and Dummy-SR3) of each stage. The source of the transistor PT30 is connected to the video signal line Video, and the drain thereof is connected to the drain line.

According to the first embodiment, the drains of those transistors PT30 in the stages which are connected to the dummy shift register circuits 4b1, 4b2, 4b3 are not connected to the drain line. The drains of the transistors PT30 connected to the dummy shift register circuits 4b1, 4b2, 4b3 may be connected to any one of the drain lines arranged in the area other than the display area contributing to the display operation. This is also the case with all the embodiments of the invention described below.

Next, with reference to FIGS. 2, 3 and 5, the operation of the shift register circuit of the H driver of the liquid crystal display according to the first embodiment is explained. In FIG. 5, reference characters Dummy-SR1, Dummy-SR2, SR1 and SR2 designate the output signals from the first-stage dummy shift register circuit 4b1, the second-stage dummy shift register 4b2, the first-stage shift register circuit 4a1 and the second-stage shift register circuit 4a2, respectively.

First, the H-level (HVDD) start signal HST is input to the first circuit section 4b11 of the first-stage dummy shift register circuit 4b1 as an initial mode. As a result, the transistors PT2, PT3 of the first circuit section 4b11 are turned off, and the transistor PT1 is turned on. Therefore, the potential of the node ND2 is at L level. Thus, the transistors PT2, PT3 of the second circuit section 4b12 are turned on. Since the potential of the node ND3 turns to H level, the transistor PT1 of the second circuit section 4b12 is turned off. In this way, the transistor PT2 of the second circuit section 4b12 is turned on, while the transistor PT1 is turned off, and therefore the potential of the node ND4 rises to H level. In the initial mode, therefore, the H-level output signal Dummy-SR1 is output from the first-stage dummy shift register circuit 4b1.

Under this condition, in the case where the L-level (HVSS) start signal HST is input, the transistors PT2, PT3 of the first circuit section 4b11 are turned on. Since the potentials of both the nodes ND1 and ND2 become H level, the transistor PT1 of the first circuit section 4b11 is held in off state. As the result of the potential of the node ND2 becoming H level, the transistors PT2, PT3 of the second circuit section 4b12 turn off. At the same time, the potential of the node ND3 is held at H level, and therefore the transistor PT1 of the second circuit section 4b12 is held in off state. The potential of the node ND4 is held at H level, and therefore the H-level output signal Dummy-SR1 is output from the first-stage dummy shift register circuit 4b1.

Next, in the first circuit section 4b11, the L-level (HVSS) clock signal HCLK1 is input through the transistor PT4. In the process, the transistor PT3 is in on state, and therefore the potential of the node ND1 is held at H level. As a result, the transistor PT1 of the first circuit section 4b11 is held in off state. Incidentally, as long as the clock signal HCLK1 remains at L level, the penetration current flows between the clock signal line HCLK1 and the positive potential HVDD through the transistors PT4, PT3 of the first circuit section 4b11. During the period when the clock signal is at L level, however, the duty factor is set to about 1/30 (L-level period: about 80 nsec to about 160 nsec). Therefore, the penetration current flows between the clock signal line HCLK1 and the positive potential HVDD only for a short period of about 80 nsec to about 160 nsec during which the clock signal is at L level.

The L-level (HVSS) clock signal HCLK1 is also input to the second circuit section 4b12 through the high resistor R1 and the transistor PT4. In the process, the transistor PT3 is in off state, and therefore the potential of the node ND3 becomes L level thereby turning on the transistor PT1. Since the transistor PT1 is not easily turned on due to the high resistor R1, the response rate is low to turn on the transistor PT1.

The transistor PT2 of the second circuit section 4b12 is in off state, and therefore, the potential of the ND4 is reduced to HVSS through the transistor PT1 in on state. In this case, the potential of the node ND3 (the gate potential of the transistor PT1) decreases with the potential of the node ND4 (the source potential of the transistor PT1) in such a manner that the gate-source voltage of the transistor PT1 is maintained by the capacitor C1. Also, the transistor PT3 of the second circuit section 4b12 is in off state and no H-level signal flows reversely from the clock signal line HCLK1 toward the node ND3. Thus, the holding voltage of the capacitor C1 (the gate-source voltage of the transistor PT1) is maintained. In this way, the transistor PT1 is kept on while the potential of the node ND4 is on the decrease, and therefore, the potential of the node ND4 drops to HVSS. As a result, the L-level output signal Dummy-SR1 is output from the first-stage dummy shift register circuit 4b1.

Incidentally, in the second circuit section 4b12, the potential of the node ND3 is lower than HVSS when the potential of the node ND4 drops to HVSS. The bias voltage applied to the transistor PT3 connected to the positive potential HVDD, therefore, is higher than the potential difference between HVDD and HVSS. Also, in the case where the clock signal HCLK1 rises to H level (HVDD), the bias voltage applied to the transistor PT4 connected to the clock signal line HCLK1 also increases beyond the potential difference between HVDD and HVSS.

Next, when the H-level (HVDD) start signal HST is input to the first circuit section 4b11, the transistors PT2 and PT3 turn off. In this case, the nodes ND1 and ND2 are held floating at H level. As a result, the other parts are not affected. Thus, the L-level output signal Dummy-SR1 from the first-stage dummy shift register circuit 4b1 is maintained.

Next, the L-level (HVSS) clock signal HCLK1 is input to the first circuit section 4b11 again through the transistor PT4. The transistor PT1 of the first circuit section 4b11 is turned on, and therefore the potential of the node ND2 drops to HVSS. In this case, the potential of the node ND1 drops with the potential decrease of the node ND2 in such a manner that the capacitor C1 maintains the gate-source voltage of the transistor PT1. Also, the transistor PT3 of the first circuit section 4b11 is in off state, and since no H-level signal flows reversely from the clock signal line HCLK1 to the node ND1, the holding voltage of the capacitor C1 is maintained in the transistor PT4. When the potential of the node ND2 drops, the transistor PT1 is normally kept on, and therefore the potential of the node ND2 drops to HVSS. Thus, the transistors PT2 and PT3 of the second circuit section 4b12 turn on. Incidentally, when the potential of the node ND2 drops to HVSS, the potential of the node ND1 is lower than HVSS.

In the process, according to the first embodiment, the transistor PT1 is turned off by the transistor PT3 of the second circuit section 4b12, and therefore both the transistors PT1 and PT2 are not turned on at the same time. As a result, the penetration current is prevented from flowing between the positive potential HVDD and the negative potential HVSS through the transistors PT1 and PT2.

In the second circuit section 4b12, the transistor PT2 is turned on while the transistor PT1 is turned off. Thus, the potential of the node ND4 rises to H level from HVSS to HVDD. As a result, from the first-stage dummy shift register circuit 4b1, the H-level output signal Dummy-SR1 is output.

As described above, according to the first embodiment, assume that the L-level clock signal HCLK1 is input while the L-level start signal HST is input to the first circuit section 4b11 of the first-stage dummy shift register circuit 4b1. The L-level output signal Dummy-SR1 is output from the second circuit section 4b12. In the case where the L-level clock signal HCLK1 is input again with the L-level output signal Dummy-SR1 output from the second circuit section 4b12, the output signal Dummy-SR1 from the second circuit section 4b12 rises to H level.

The output signal Dummy-SR1 from the second circuit section 4b12 of the first-stage dummy shift register circuit 4b1 is input to the first circuit section 4b21 of the second-stage dummy shift register circuit 4b2. Assume that the L-level clock signal HCLK2 is input in the case where the L-level output signal Dummy-SR1 of the first-stage dummy shift register circuit 4b1 is input to the first circuit section 4b21 of the second-stage dummy shift register circuit 4b2. The L-level output signal Dummy-SR2 is output from the second circuit section 4b22. Further, in the first-stage shift register circuit 4a1 connected with the second-stage dummy shift register circuit 4b2, assume that the L-level clock signal HCLK1 is input in the case where the L-level output signal Dummy-SR2 of the second-stage dummy shift register circuit 4b2 is input to the first circuit section 4a11. The L-level output signal SR1 is output from the second circuit section 4a12. Also, in the second-stage shift register circuit 4a2 connected with the first-stage shift register circuit 4a1, assume that the L-level clock signal HCLK2 is input in the case where the L-level output signal SR1 of the first-stage shift register circuit 4a1 is input to the first circuit section 4a21, the L-level output signal SR1 is output from the second circuit section 4a22. In this way, the output signal of the shift register circuit in a given stage is input to the shift register circuit in the next stage, and the clock signals HCLK1 and HCLK2 which reach L level at different timings are input to the shift registers in each stage alternately with each other. As a result, the timing at which the L-level output signal is output from the shift register circuits in each stage is shifted.

The L-level signals with timings shifted are input to the transistor PT30 of each stage of the horizontal switch 3, so that the transistors PT30 of each stage are sequentially turned on. As a result, the drain line in each stage is supplied with the video signal from the video signal line Video, and therefore the drain lines of each stage are sequentially driven (scanned). By the way, in the transistors PT30 supplied with the output signals Dummy-SR1, Dummy-SR2 and Dummy-SR3 of the dummy shift register circuits 4b1, 4b2, 4b3, the drain is not connected to the drain line. Even in the case where the transistor PT30 is turned on, therefore, no video signal is supplied to the drain line. As described above, the transistor PT30 may be connected to the drain line arranged in the area other than the display area, and the drain line may or may not be supplied with the video signal.

At the end of scanning the drain lines in all the stages connected to one gate line, the next gate line is selected. After sequentially scanning the drain lines of each stage, the next gate line is selected. This operation is repeated until the end of scanning the drain line of each stage connected to the last gate line thereby to end the scanning of one screen.

According to the first embodiment, as described above, the first circuit section 4b11 and the second circuit section 4b12 include the transistor PT3 for turning off the transistor PT1 when the transistor PT2 is on. In this way, the transistor PT1 connected to the negative potential HVSS and the transistor PT2 connected to the positive potential HVDD are prevented from turning on at the same time. In the first circuit section 4b11 and the second circuit section 4b12, therefore, the penetration current is prevented from flowing between the negative potential HVSS and the positive potential HVDD through the transistors PT1 and PT2. As a result, the increase in the current consumption of the liquid crystal display is suppressed.

According to the first embodiment, the two stages of dummy shift register circuits 4b1, 4b2 not connected to the drain line are arranged in the stage before (the operation starting side) the plurality of stages of shift register circuits 4a1, 4a2, . . . , 4an connected to the drain line. In this way, the shift register circuit in the second stage from the operation starting side constitutes the second-stage dummy shift register circuit 4b2 not connected to the drain line. Therefore, display irregularities can be prevented from occurring in an area corresponding to the second-stage shifter register circuit as counted from the operation starting side. Also, since the dummy shift register circuit 4b3 not connected to the drain line is arranged in the stage next to the last stage (shift register 4an) of the plurality of stages of shift register circuits 4a1, 4a2, . . . , 4an connected to the drain line, the last-stage shift register circuit makes up the dummy shift register circuit 4b3 not connected to the drain line. Therefore, display irregularities are prevented from occurring in an area corresponding to the last-stage shift register circuit.

According to the first embodiment, the transistors PT1 to PT4 of the first circuit section 4b11 and the second circuit section 4b12 and the transistors making up the capacitor C1 are all configured of TFTs (thin film transistors) formed of p-type MOS transistors (field effect transistors). As compared with the shift register circuit including two conductive types of transistors, therefore, the number of ion injection steps and the ion injection masks can be reduced. As a result, the fabrication process is simplified while at the same time reducing the fabrication cost. Also, the p-type field effect transistor, unlike the n-type field effect transistor, requires no LDD (lightly doped drain) structure, and therefore the fabrication process can be further simplified. Except for these advantages, the transistors PT1, PT2, PT3 may be n-channel transistors.

According to the first embodiment, the transistors PT3 and PT4 are configured to have two gate electrodes 91 and 92 electrically connected to each other. Thus, the voltage applied between the source and the drain of the transistors PT3 and PT4 is distributed, about half by half (depending on the transistor size, etc.), between the source-drain circuit corresponding to the gate electrode 91 and the source-drain circuit corresponding to the gate electrode 92. Even in the case where the bias voltage applied between the source and the drain of the transistors PT3 and PT4 increases beyond the potential difference between HVSS and HVDD, therefore, a voltage lower than the potential difference between HVSS and HVDD is applied to the source-drain circuit corresponding to the gate electrode 91 and the source-drain circuit corresponding to the gate electrode 92 of the transistors PT3 and PT4. Also, the voltage applied between the gate and the source of the transistors PT3 and PT4 is distributed, about half by half (depending on the transistor size, etc.), between the source-drain circuit corresponding to the gate electrode 91 and the source-drain circuit corresponding to the gate electrode 92. Even in the case where the bias voltage applied between the gate and the source of the transistors PT3 and PT4 increases beyond the potential difference between HVSS and HVDD, therefore, a voltage lower than the potential difference between HVSS and HVDD is applied to the gate-source circuit corresponding to the gate electrode 91 and the gate-source circuit corresponding to the gate 92 of the transistors PT3 and PT4. As a result, the deterioration of the characteristics of the transistors PT3 and PT4 is suppressed which otherwise might be caused by the application of a bias voltage higher than the potential difference between HVSS and HVDD to the transistors PT3 and PT4, thereby making it possible to prevent the scanning characteristic of the liquid crystal display including the shift register circuits from being deteriorated.

Second Embodiment

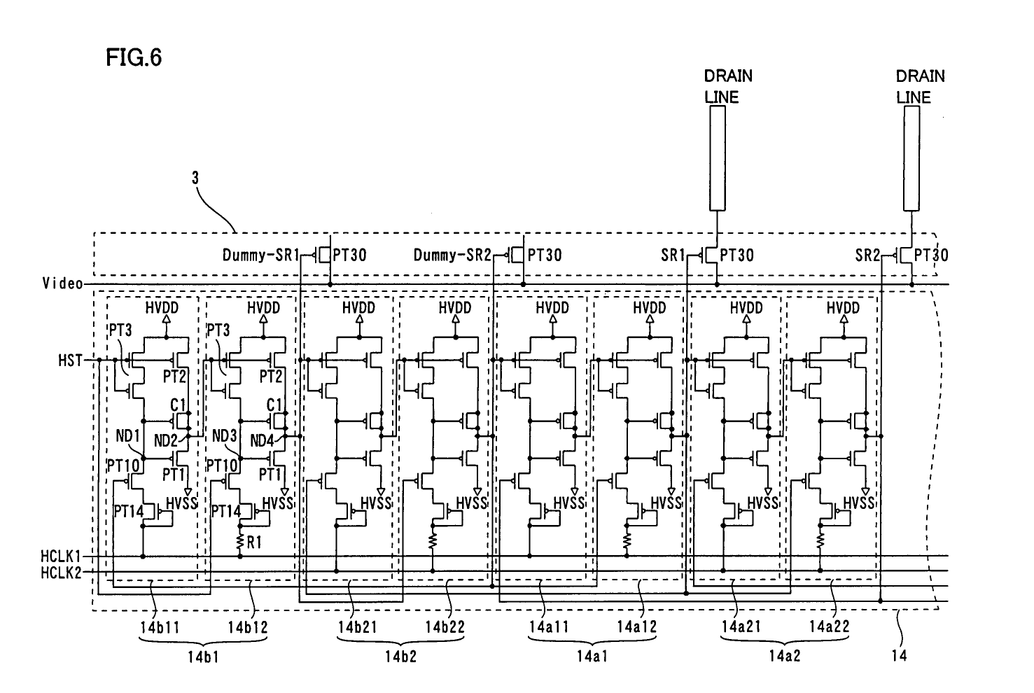

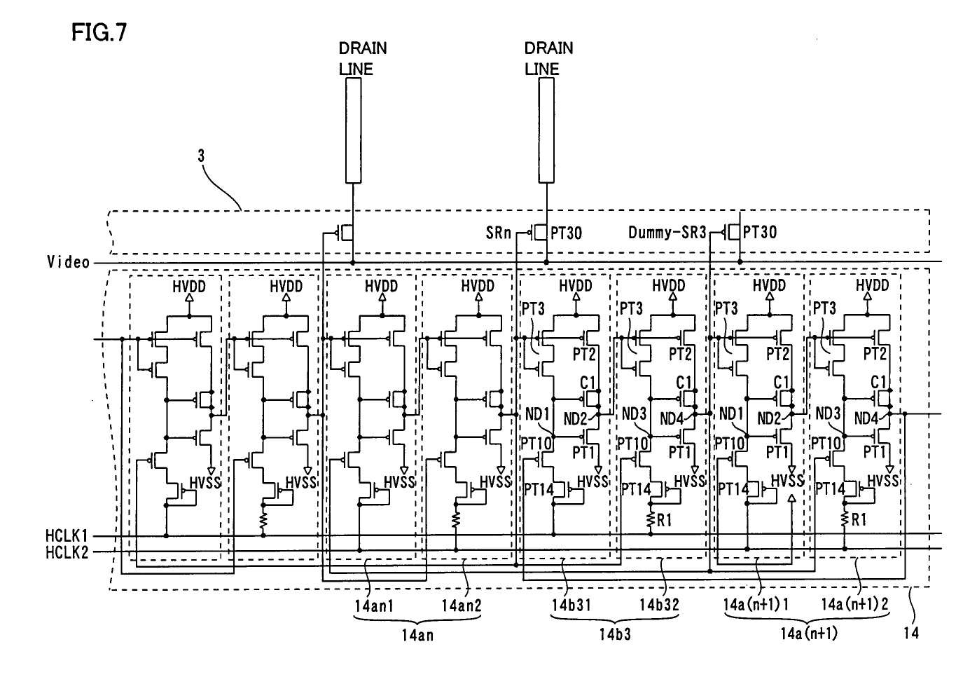

With reference to FIGS. 6 and 7, an example of the H driver according to the second embodiment is explained which can suppress the display irregularities and the penetration current flow more than in the first embodiment. First, an explanation is given about the circuit configuration of the H driver of a liquid crystal display according to the second embodiment.

The H driver 14 of the liquid crystal display according to the second embodiment, as shown in FIGS. 6 and 7, includes a plurality of stages of shift register circuits 14a1, 14a2, . . . , 14an connected to the drain lines.

According to the second embodiment, the dummy shift register circuits 14b1, 14b2 are arranged in two stages before the shift register circuits 14a1, 14a2, . . . , 14an connected to the drain lines. Also, according to the second embodiment, as shown in FIG. 7, the dummy shift register circuit 14b3 is arranged in the stage next to the last stage of the shift register circuits 14a1, 14a2, 14an connected to the drain lines. The dummy shift register circuits 14b1, 14b2 are an example of “the first dummy shift register circuit” according to the invention. Also, the dummy shift register circuit 14b3 is an example of “the second dummy shift register circuit” according to the invention.

According to this embodiment, as shown in FIG. 6, the start signal HST is input to the first-stage (initial) dummy shift register circuit 14b1. As a result, as compared with a case in which the dummy shift register circuits 14b1, 14b2 in two stages are lacking, the position of the shift register circuit supplied with the start signal HST can be displaced by two stages forward, and therefore the timing of inputting the start signal HST can be advanced by two clocks.

Also, the first-stage dummy shift register circuit 14b1 is configured of the first circuit section 14b11 and the second circuit section 14b12. The first circuit section 14b11 and the second circuit section 14b12 are an example of “the first circuit section” according to the invention. The first circuit section 14b11 and the second circuit section 14b12 include p-channel transistors PT1, PT2, PT3, PT10, a diode-connected p-channel transistor PT14 and a capacitor C1 formed by connecting the source and the drain of the p-channel transistor.

Specifically, the first circuit section 14b11 and the second circuit section 14b12 according to the second embodiment, as compared with the circuit configuration of the first circuit section 4b11 and the second circuit section 4b12 (FIG. 2) according to the first embodiment, further include the p-channel transistor PT10. At the same time, according to the second embodiment, the p-channel transistor PT14 is formed of a normal field effect transistor having only one gate electrode. Also, the second circuit section 14b12, unlike the first circuit section 14b11, further includes a high resistor R1.

Also, according to the second embodiment, the p-channel transistors PT1 to PT3, PT10 and PT14 of the first circuit section 14b11 and the second circuit section 14b12 and the p-channel transistor making up the capacitor C1 are all formed of a TFT (thin film transistor) including a p-type MOS transistor (field effect transistor). In the description that follows, the p-channel transistors PT1 to PT3, PT10 and PT14 are hereinafter referred to as the transistors PT1 to PT3, PT10 and PT14, respectively.

According to the second embodiment, the transistor PT3, like the transistor PT3 of the dummy shift register circuit 4b1 (FIG. 2) according to the first embodiment, is formed to have two gate electrodes 91, 92 (FIG. 4) electrically connected to each other.

Also, as shown in FIG. 6, the source of the transistor PT1 of the first circuit section 14b11 is connected to the node ND2, and the drain thereof is connected to the negative potential HVSS. The gate of the transistor PT1 is connected to the node ND1 and supplied with the clock signal HCLK1. The source of the transistor PT2 is connected to the positive potential HVDD and the drain thereof is connected to the node ND2. The gate of the transistor PT2 is supplied with the start signal HST.

According to the second embodiment, the transistor PT3 is connected between the gate of the transistor PT1 and the positive potential HVDD. The gate of the transistor PT3 is supplied with the start signal HST. The transistor PT3 turns off the transistor PT1 when the transistor PT2 is in on state. As a result, the transistor PT2 and the transistor PT1 are prevented from tuning on at the same time.

According to the second embodiment, the capacitor C1 is connected between the gate and the source of the transistor PT1. Also, the source of the transistor PT14 is connected to the node ND1 and the drain thereof is connected to the clock signal line HCLK1.

According to the second embodiment, the transistor PT10 is connected between the transistor PT14 and the node ND1. Specifically, the source of the transistor PT10 is connected to the node ND1, while the drain thereof is connected to the source of the transistor PT14. The gate of the transistor PT10 is supplied with the output signal Dummy-SR2 of the dummy shift register circuit 14b2 in the next stage. Incidentally, the transistor PT10 is an example of “the fifth transistor” according to the invention.

The circuit configuration of the second circuit section 14b12 is basically similar to that of the first circuit section 14b11. In the second circuit section 14b12, however, the source of the transistor PT1 and the drain of the transistor PT2 are connected to the node ND4, and the gate of the transistor PT1 is connected to the node ND3. Also, the gate of the transistor PT10 of the second circuit section 14b12 is supplied with the start signal HST. The high resistor R1 is connected between the transistor PT14 and the clock signal line HCLK1.

The output signal Dummy-SR1 of the first-stage dummy shift register circuit 14b1 is output from the node ND4 (output node) of the second circuit section 14b12. The node ND4 (output node) of the first-stage dummy shift register circuit 14b1 is connected with the second-stage dummy shift register circuit 14b2.

The second-stage dummy shift register circuit 14b2, the plurality of stages of the shift register circuits 14a1, 14a2, . . . , 14an, 14a(n+1) and the last-stage dummy shift register 14b3 have a similar circuit configuration to the first-stage dummy shift register circuit 14b1. Specifically, the second-stage dummy shift register circuit 14b2 and the last-stage dummy shift register circuit 14b3 are configured of the first circuit sections 14b21, 14b31 and the second circuit sections 14b22, 14b32, respectively, having a similar configuration to the first circuit section 14b11 and the second circuit section 14b12 of the first-stage dummy shift register circuit 14b1. Also, the plurality of stages of the shift register circuits 14a1, 14a2, . . . , 14an, 14a(n+1) are configured of the first circuit sections 14a11, 14a21, . . . , 14an1, 14a(n+1)1 and the second circuit sections 14a12, 14a22, . . . , 14an2, 14a(n+1)2, respectively, having a similar configuration to the first circuit section 14b11 and the second circuit section 14b12 of the first-stage dummy shift register circuit 14b1.

According to the second embodiment, the gate of the transistor PT10 of the first circuit section in a predetermined stage (except for the last stage) is supplied with the output signal of the shift register circuit of the next stage. The gate of the transistor PT10 of the second circuit section is supplied with the output signal of the shift register circuit of the preceding stage or the start signal HST.

As shown in FIG. 7, the gate of the transistor PT10 of the first circuit section 14a(n+1)1 of the shift register circuit 14a(n+1) connected to the last-stage dummy shift register circuit 14b3 but not to the horizontal switch 3 is connected to the negative potential HVSS. The gate of the transistor PT10 of the first circuit section 14a(n+1)1 of the shift register circuit 14a(n+1), therefore, is always supplied with a L-level signal.

As shown in FIGS. 6 and 7, the horizontal switch 3 has a transistor PT30 in each stage. The gate of the transistor PT30 in each stage is connected to the node ND4 providing an output node of each stage. The transistor PT30 of each stage, therefore, is supplied with the output signals (Dummy-SR1, Dummy-SR2, SR1, SR2, . . . , SRn, and Dummy-SR3) of each stage. The source of this transistor PT30 is connected to the video signal line Video and the drain thereof is connected to the drain line. Incidentally, of all the transistors PT30 connected in the stages, the drain of the transistor PT30 connected to each of the dummy shift register circuits 14b1, 14b2, 14b3 is not connected to the drain line.

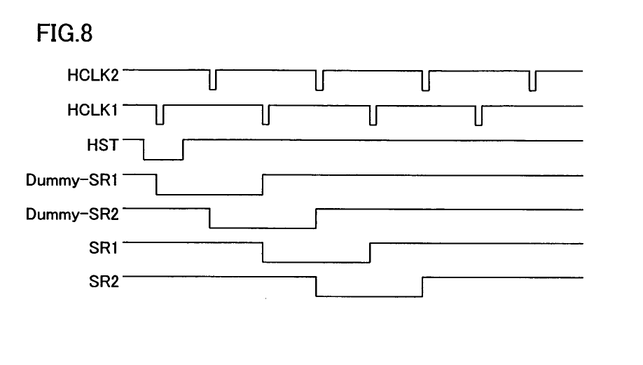

Next, referring to FIGS. 6 to 8, the operation of the H-driver shift register circuit of the liquid crystal display according to the second embodiment is explained. In FIG. 8, reference characters Dummy-SR1, Dummy-SR2, SR1 and SR2 designate the output signals from the first-stage dummy shift register circuit 14b1, the second-stage dummy shift register circuit 14b2, the first-stage shift register circuit 14a1 and the second-stage shift register circuit 14a2, respectively.

In the initial state, the output signals Dummy-SR1 to Dummy-SR3 and SR1 to SRn of all the dummy shift register circuits 14b1, 14b2, 14b3 and the shift register circuits 14a1 to 14an are at H level. In the case where the L-level start signal HST is input under this condition, the transistors PT2 and PT3 of the first circuit section 14b11 of the first-stage dummy shift register circuit 14b1 turn on. After that, the L-level clock signal HCLK1 is input to the gate of the transistor PT14 of the first circuit section 14b11 and the gate of the transistor PT14 of the second circuit section 14b12. As a result, the transistor PT14 of the first circuit section 14b11 and the transistor PT14 of the second circuit section 14b12 are turned on. The response rate to turn on the transistor PT14 of the second circuit section 14b12 is delayed by the high resistor R1.

In the process, according to the second embodiment, the gate of the transistor PT10 of the first circuit section 14b11 of the first-stage dummy shift register circuit 14b1 is supplied with the H-level output signal Dummy-SR2 of the second-stage dummy shift register circuit 14b2, so that the transistor PT10 is turned off. As a result, even in the case where the transistors PT3 and PT4 of the first circuit section 14b11 are in on state, no penetration current flows along the clock signal line HCLK1 from HVDD through the transistors PT3 and PT14.

In the first circuit section 14b11, the transistor PT3 is in on state while the transistor PT10 is in off state, and therefore the potential of the node ND1 rises to H level. The transistor PT1 of the first circuit section 14b11 turns off. In this case, since the transistor PT2 is on, the potential of the node ND2 rises to H level. The transistors PT2 and PT3 of the second circuit section 14b12 are thus turned off.

In the process, according to the second embodiment, the gate of the transistor PT10 of the second circuit section 14b12 is supplied with the L-level start signal HST, and therefore the transistor PT10 is in on state. As a result, the potential of the node ND3 drops to L level, and the transistor PT1 of the second circuit section 14b12 is turned on. Under this condition, the transistor PT2 of the second circuit section 14b12 is in off state, and therefore the potential of the node ND4 drops to HVSS.

At the same time, the potential of the node ND3 (the gate potential of the transistor PT1) drops with the decrease in the potential of the node ND4 (the source potential of the transistor PT1) in such a manner that the gate-source voltage of the transistor PT1 is maintained by the capacitor C1 of the second circuit section 14b12. Also, in the second circuit section 14b12, the transistor PT3 is off, and the H-level clock signal HCLK1 from the clock signal line is prevented from flowing in reverse direction in the transistor PT14 toward the node ND3. Therefore, the holding voltage of the capacitor C1 (the gate-source voltage of the transistor PT1) is maintained. According as the potential of the node ND4 decreases, therefore, the transistor PT1 of the second circuit section 14b12 is kept on, so that the potential of the node ND4 drops to HVSS. As a result, the L-level output signal Dummy-SR1 is output form the first-stage dummy shift register circuit 14b1.

In the second circuit section 14b12, the potential of the node ND3 is lower than HVSS when the potential of the node ND4 drops to HVSS. The bias voltage applied to the transistor PT3 connected to the positive potential HVDD, therefore, increases beyond the potential difference between HVDD and HVSS.

Next, the clock signal HCLK1 rises to H level thereby to turn off the transistor PT14 of the first circuit section 14b11 and the transistor PT14 of the second circuit section 14b12. After that, the start signal HST rises to H level, thereby turning off the transistors PT2, PT3 of the first circuit section 14b11 and the transistor P10 of the second circuit section 14b12. In this case, the nodes ND1 and ND2 are held floating at H level. Also, the potential of the node ND4 is held at HVSS (L level) by the capacitor C1 and the transistor PT14 in off state of the second circuit section 14b12. Thus, the L-level output signal Dummy-SR1 continues to be output from the first-stage dummy shift register circuit 14b1.

The L-level output signal Dummy-SR1 of the first-stage dummy shift register circuit 14b1 is supplied to the first circuit section 14b21 of the second-stage dummy shift register circuit 14b2. Under this condition, assume that the second-stage dummy shift register circuit 14b2 is supplied with the L-level clock signal HCLK2. The second-stage dummy shift register 14b2 operates in the same way as in the case where the first-stage shift register circuit 14b1 is supplied with the L-level start signal HST and the L-level clock signal HCLK1. As a result, the L-level output signal Dummy-SR2 is output from the second-stage dummy shift register circuit 14b2.

Next, the clock signal HCLK1 drops again to L level, thereby turning on the transistor PT14 of the first circuit section 14b11 and the transistor PT14 of the second circuit section 14b12.

In the process, according to the second embodiment, the gate of the transistor PT10 of the first circuit section 14b11 of the first-stage dummy shift register circuit 14b1 is supplied with the L-level output signal Dummy-SR2 of the second-stage dummy shift register circuit 14b2. Therefore, the transistor PT10 of the first circuit section 14b11 is turned on. Since the transistor PT1 of the first circuit section 14b11 is thus turned on, the node ND2 drops to L level. As a result, the transistors PT2 and PT3 of the second circuit section 14b12 are turned on.

At the same time, according to the second embodiment, the gate of the transistor PT10 of the second circuit section 14b12 is supplied with the H-level start signal HST, thereby turning off the transistor PT10. Even in the case where the transistors PT3 and PT14 are turned on in the second circuit section 14b12, therefore, no penetration current flows to the clock signal line HCLK1 from HVDD through the transistors PT3 and PT14.

Also, the transistor PT3 of the second circuit section 14b12 is in on state and the transistor PT10 in off state. Therefore, the potential of the node ND3 rises to H level. Since the transistor PT1 of the second circuit section 14b12 is turned off, the potential of the node ND4 rises to HVDD. As a result, the H-level output signal Dummy-SR1 is output from the first-stage dummy shift register circuit 14b1.

As described above, according to the second embodiment, the L-level output signal Dummy-SR1 is output from the second circuit section 14b12 in the case where the L-level clock signal HCLK1 is input with the L-level start signal HST input to the first circuit section 14b11 of the first-stage dummy shift register circuit 14b1. In the case where the L-level clock signal HCLK1 is input again with the L-level output signal Dummy-SR1 output from the second circuit section 14b12, on the other hand, the output signal Dummy-SR1 from the second circuit section 14b12 rises to H level. The output signal Dummy-SR1 from the first-stage dummy shift register circuit 14b1 is input to the first circuit section 14b21 of the second-stage dummy shift register circuit 14b2. In this way, the L-level output signal from the shift register circuit in a given stage is input to the shift register circuit in the next stage, while at the same time the clock signals HCLK1 and HCLK2 falling to L level at different timings are input alternately to the shift register circuit of each stage. Thus, the timing at which the L-level output signal is output from the shift register circuit of each stage is shifted.

The L-level signals shifted in timing are input to the transistor PT30 of each stage of the horizontal switch 3, so that the transistors PT30 of each stage are sequentially turned on. In this way, the drain line of each stage is supplied with the video signal from the video signal line Video. The drain lines of each stage are thus sequentially driven (scanned). Incidentally, the drain of the transistor PT30 supplied with the output signals Dummy-SR1, Dummy-SR2 and Dummy-SR3 of the dummy shift register circuits 14b1, 14b2 and 14b3, respectively, is not connected to the drain line. Even in the case where the transistor PT30 is turned on, therefore, the video signal is not supplied to the drain line.

Once the scanning of the drain lines of all the stages connected to one gate line is complete, the next gate line is selected. After the drain lines of all the stages are sequentially scanned, the next gate is selected. This operation is repeated until the scanning of the last gate line is completed thereby to end the scanning of one screen.

As shown in FIG. 7, the gate of the transistor PT10 of the first circuit section 14a(n+1)1 of the shift register circuit 14a(n+1) connected to the last-stage dummy shift register circuit 14b3 but not connected to the horizontal switch 3 is always supplied with the L-level signal. Therefore, the transistor PT10 of the first circuit section 14a(n+1)1 is kept on.

According to the second embodiment, as described above, the provision of the transistor PT10 of the first circuit section operated to turn on in response to the output signal SR(m+1) in the next stage and the transistor PT10 of the second circuit section operated to turn on in response to the output signal SR(m−1) in the preceding stage or the start signal HST eliminates a case in which the output signal SR(m+1) in the next stage and the output signal R(m−1) in the preceding stage simultaneously assume L level. Therefore, the transistor PT10 of the first circuit section and the transistor P10 of the second circuit section are not turned on at the same time. Also, since the transistor PT3 of the first circuit section is turned on in response to the output signal SR(m−1) in the preceding stage or the start signal HST, the transistor PT10 and the transistor PT3 of the first circuit section are not turned on at the same time. In the first circuit section, therefore, a penetration current is prevented from flowing between the positive potential HVDD and the clock signal line through the transistors PT10 and PT3. Also, the transistor PT3 of the second circuit section is turned off during the period when the transistor PT10 of the second circuit section operated to turn on in response to the output signal SR(m−1) in the preceding stage or the start signal HST is in on state. In the second circuit section, therefore, the transistor PT10 and the transistor PT3 are not turned on at the same time. As a result, the penetration current is prevented from flowing between the positive potential HVDD and the clock signal line through the transistors PT10 and PT3 in the second circuit section.

According to the second embodiment, like in the first embodiment described above, the penetration current is prevented from flowing between the positive potential HVDD and the negative potential HVSS through the transistors PT1 and PT2 by the transistor PT3 for turning off the transistor PT1 when the transistor PT2 is in on state. According to the second embodiment, therefore, the penetration current is prevented from flowing between the positive potential HVDD and the clock signal line through the transistors PT3 and PT10 as well as between the positive potential HVDD and the negative potential HVSS through the transistors PT1 and PT2. As compared with the first embodiment, therefore, the increase in the power consumption of the liquid crystal display can be suppressed more.

According to the second embodiment, two stages of dummy shift register circuits 14b1 and 14b2 not connected to the drain line are arranged in the stage (operation starting side) preceding to the plurality of stages of shift register circuits 14a1, 14a2, . . . , 14an connected to the drain line. Therefore, the dummy shift register circuit 14b2 not connected to the drain line assumes the second-stage shift register circuit from the operation starting side. Thus, the display irregularities can be prevented from occurring in an area corresponding to the second-stage shift register circuit as counted from the operation starting side. Also, in view of the fact that the dummy shift register circuit 14b3 not connected to the drain line is arranged in the stage following the last stage (shift register circuit 14an) of the plurality of stages of the shift register circuits 14a1, 14a2, . . . , 14an connected to the drain line, the dummy shift register circuit 14b3 not connected to the drain line represents the last-stage shift circuit. Therefore, the occurrence of display irregularities in an area corresponding to the last-stage shift register circuit is suppressed.

The other effects of the second embodiment are similar to those of the first embodiment.

Third Embodiment

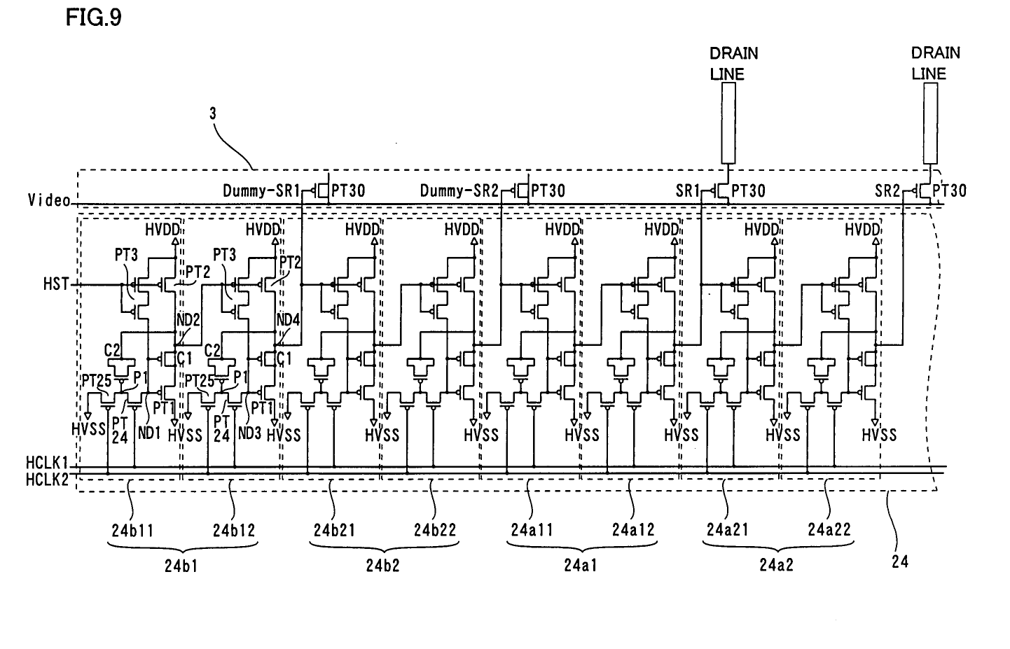

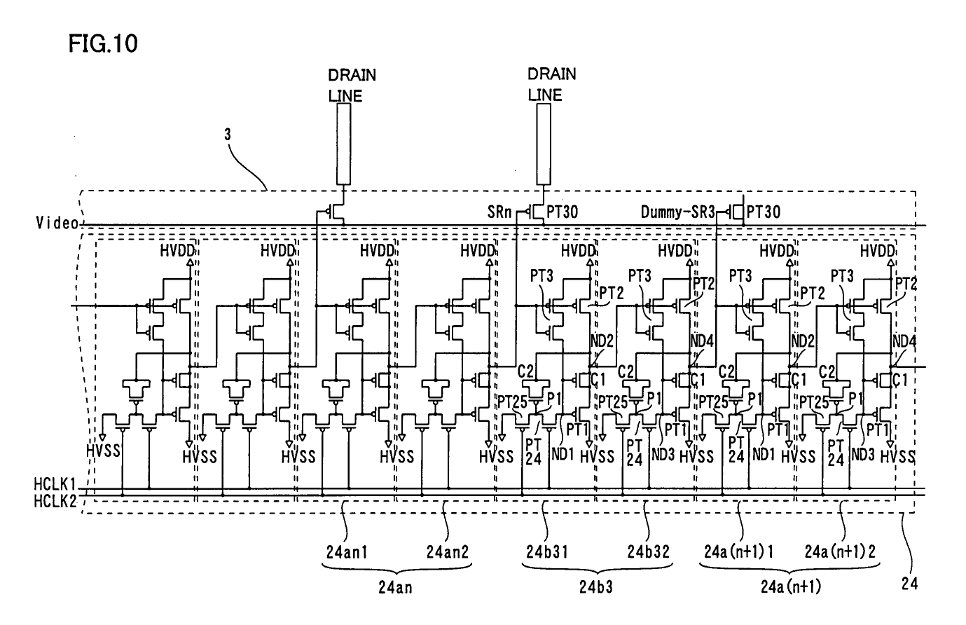

FIGS. 9 and 10 show a third embodiment of the invention. An explanation is given below about another example of the H driver capable of suppressing the penetration current more than in the first embodiment as well as suppressing the display irregularities. First, with reference to FIGS. 9 and 10, the circuit configuration of the H driver of the liquid crystal display according to the third embodiment is explained.

The H driver 24 of the liquid crystal display according to the third embodiment, as shown in FIGS. 9 and 10, includes a plurality of stages of shift register circuits 24a1, 24a2, . . . , 24an connected to the drain line.

According to the third embodiment, two stages of dummy shift register circuits 24b1 and 24b2 not connected to the drain line are arranged in the stage preceding to the shift register circuits 24a1, 24a2, . . . , 24an connected to the drain line. Also, according to the third embodiment, as shown in FIG. 10, a dummy shift register 24b3 is arranged in the stage following the last stage of the shift register circuits 24a1, 24a2, . . . , 24an connected to the drain line. The dummy shift register circuit 24b3 is followed by the stage of the shift register circuit 24a(n+1) not connected to the horizontal switch 3. The dummy shift register circuits 24b1, 24b2 represent an example of “the first dummy shift register circuit” according to the invention. The dummy shift register circuit 24b3, on the other hand, represents an example of “the second dummy shift register circuit” according to the invention.

According to the third embodiment, as shown in FIG. 9, the start signal HST is input to the first-stage (initial stage) dummy shift register circuit 24b1. As compared with a case lacking the two stages of dummy shift register circuits 24b1, 24b2, therefore, the position of the shift register circuit supplied with the start signal HST can be displaced forward by two stages, so that the timing of inputting the start signal HST can be advanced by two clocks.

The first-stage dummy shift register circuit 24b1 includes the first circuit section 24b11 and the second circuit section 24b12. The first circuit section 24b11 and the second circuit section 24b12 are an example of “the first circuit section” according to the invention. The first circuit section 24b11 and the second circuit section 24b12 include p-channel transistors PT1, PT2, PT3, PT24, PT25 and capacitors C1, C2 formed to connect the source and the drain of the p-channel transistors.

Specifically, the first circuit section 24b11 and the second circuit section 24b12 according to the third embodiment have such a circuit configuration that the p-channel transistor PT4 of the first circuit section 4b11 and the second circuit section 4b12 (FIG. 2) according to the first embodiment is replaced by the p-channel transistors PT24, PT25, and the capacitor C2 is added between the node ND2 and the contact point P1 between the p-channel transistor PT24 and the p-channel transistor PT25. The p-channel transistor PT24 and the p-channel transistor PT25 are an example of “the fourth transistor” and “the fifth transistor”, respectively, according to the invention. The capacitor C2, on the other hand, is an example of “the second capacitor” according to the invention.

According to the third embodiment, the p-channel transistors PT1 to PT3, PT24, PT25 of the first circuit section 24b11 and the second circuit section 24b12 and the p-channel transistors making up the capacitors C1, C2 are all configured of a TFT (thin film transistor) formed of a MOS transistor (field effect transistor). The p-channel transistors PT1 to PT3, PT24, PT25 are hereinafter referred to as the transistors PT1 to PT3, PT24, PT25, respectively.

According to the third embodiment, the transistor PT3, like the transistor PT3 of the dummy shift register circuit 4b1 (FIG. 2) according to the first embodiment, is formed to have two electrically-connected gate electrodes 91, 92 (FIG. 4).

As shown in FIG. 9, the source of the transistor PT1 of the first circuit section 24b11 is connected to the node ND2, and the drain thereof is connected to the negative potential HVSS. Also, the gate of the transistor PT1 is connected to the node ND1. The source of the transistor PT2 is connected to the positive potential HVDD, and the drain thereof is connected to the node ND2. The gate of this transistor PT2 is supplied with the start signal HST.

According to the third embodiment, the transistor PT3 is connected between the gate of the transistor PT1 and the positive potential HVDD. The gate of the transistor PT3 is supplied with the start signal HST. The transistor PT3 is provided for turning off the transistor PT1 when the transistor PT2 is in on state. As a result, the transistor PT2 and the transistor PT1 are prevented from turning on at the same time.

According to the third embodiment, the capacitor C1 is interposed between the gate and the source of the transistor PT1. Also, according to the third embodiment, the transistor PT24 is connected between the negative potential HVSS and the node ND1 connected with the gate of the transistor PT1. The gate of this transistor PT24 is supplied with the clock signal HCLK1. The transistor PT25 is connected between the transistor PT24 and the negative potential HVSS. The gate of the transistor PT25 is supplied with the clock signal HCLK2 as an inverted version of the clock signal HCLK1. The clock signal HCLK1 and the clock signal HCLK2 are generated from one clock signal in the drive IC 6 (FIG. 1). The clock signal HCLK1 and the clock signal HCLK2 are an example of “the first signal” and the “second signal”, respectively, according to the invention.

The node ND2 of the first circuit section 24b11 is connected with the second circuit section 24b12. The circuit configuration of the second circuit section 24b12 is similar to that of the first circuit section 24b11. In the second circuit section 24b12, however, the source of the transistor PT1 and the drain of the transistor PT2 are connected to the node ND4, and the gate of the transistor PT1 is connected to the node ND3.

The output signal Dummy-SR1 of the first-stage dummy shift register circuit 24b1 is output from the node ND4 (output node) of the second circuit section 24b12. The node ND4 (output node) of the first-stage dummy shift register circuit 24b1 is connected to the second-stage dummy shift register circuit 24b2.

The second-stage dummy shift register circuit 24b2, the plurality of stages of shift register circuits 24a1, 24a2, . . . , 24an, 24a(n+1) and the last-stage dummy shift register circuit 24b3 have a similar circuit configuration to the first-stage dummy shift register circuit 24b1 described above. Specifically, the second-stage dummy shift register circuit 24b2 and the last-stage dummy shift register circuit 24b3 are configured of the first circuit sections 24b21, 24b31 and the second circuit sections 24b22, 24b32 having a similar configuration to the first circuit section 24b11 and the second circuit section 24b12, respectively, of the first-stage dummy shift register circuit 24b1. Also, the plurality of the shift register circuits 24a1, 24a2, . . . , 24an, 24a(n+1) are configured of the first circuit sections 24a11, 24a21, . . . , 24an1, 24a(n+1)1 and the second circuit sections 24a12, 24a22, 24an2, 24a(n+1)2 having a similar configuration to the first circuit section 24b11 and the second circuit section 24b12, respectively, of the first-stage dummy shift register circuit 24b1. The first circuit section of the shift register circuit in the following stage is connected to the output node of the shift register circuit in the preceding stage.

As shown in FIGS. 9 and 10, the horizontal switch 3 has a transistor PT30 for each stage. The gate of the transistor PT30 of each stage is connected to the node ND4 providing an output node of each stage. As a result, the transistor PT30 of each stage is supplied with the output signal of each stage (Dummy-SR1, Dummy-SR2, SR1, SR2, SRn and Dummy-SR3). The source of the transistor PT30 is connected to the video signal line Video, and the drain thereof is connected to the drain line. Incidentally, of all the transistors PT30 connected in each stage, the drain of the transistors PT30 connected to the dummy shift register circuits 24b1, 24b2, 24b3 is not connected to the drain line.

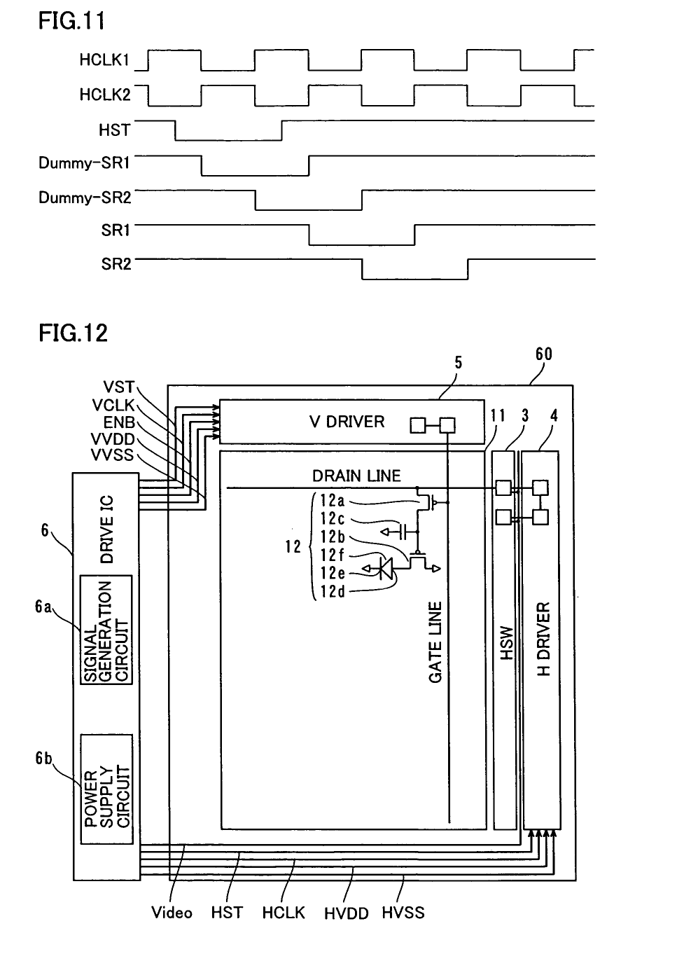

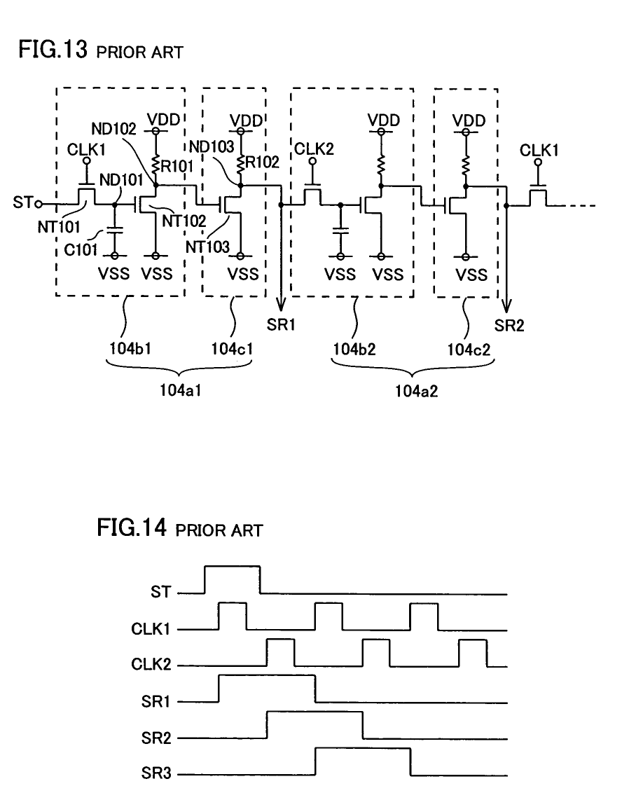

Next, with reference to FIGS. 9 to 11, the operation of the H-driver shift register circuit of the liquid crystal display according to the third embodiment is explained below. In FIG. 11, reference characters Dummy-SR1, Dummy-SR2, SR1, SR2 designate the output signals from the first-stage dummy shift register circuit 24b1, the second-stage dummy shift register circuit 24b2, the first-stage shift register circuit 24a1 and the second-stage shift register circuit 24a2, respectively.

First, as an initial mode, the H-level start signal HST is input to the first circuit section 24b11 of the first-stage dummy shift register circuit 24b1. Since the transistor PT2 is turned off thereby, the potential of the node ND2 drops to L level. The transistors PT2 and PT3 of the second circuit section 24b12 are thus turned on. The turning on of the transistor PT3 of the second circuit section 24b12 raises the potential of the node ND3 to H level, and therefore the transistor PT1 is turned off. In this way, in the second circuit section 24b12, the transistor PT2 is turned on while turning off the transistor PT1, and therefore the potential of the node ND4 rises to H level. As a result, in initial stage, the H-level output signal Dummy-SR1 is output from the second circuit section 24b12 of the first-stage dummy shift register circuit 24b1.

In this initial mode, the H-level clock signal HCLK1 input to the transistor PT24 of the first circuit section 24b11 and the second circuit section 24b12, while the L-level clock signal HCLK2 is input to the transistor PT25. As a result, in the first circuit section 24b11 and the second circuit section 24b12, the transistor PT24 is turned off and the transistor PT25 is turned on.

At the same time, according to the third embodiment, in the first circuit section 24b11 and the second circuit section 14b12, the L-level charge is supplied from the negative potential HVSS through the transistor PT25. This L-level charge is stored in the capacitor C2 connected between the source of the transistor PT1 and the contact point P1 between the transistors PT24 and PT25.

When the L-level start signal HST is input under this condition, the transistors PT2, PT3 of the first circuit section 24b11 are turned on. As a result, the potentials of the node ND1 and the node ND2 both rise to H level, and therefore the transistor PT1 is held in off state. The rise of the potential of the node ND2 to H level turns off the transistors PT2, PT3 of the second circuit section 24b12. In the process, the potential of the node ND3 is held at H level, and therefore the transistor PT1 of the second circuit section 24b12 is held in off state. Thus, the potential of the node ND4 is held at H level. In this way, the H-level output signal Dummy-SR1 is output from the second circuit section 24b12.

Next, the clock signal HCLK1 input to the transistor PT24 of the first circuit section 24b11 drops to L level, and the clock signal HCLK2 input to the transistor PT25 rises to H level.

In the process, according to the third embodiment, the transistor PT24 of the first circuit section 24b11 is turned on, while the transistor PT25 is turned off. In this case, the turning off of the transistor PT25 suppresses the penetration current from flowing between the negative potential HVSS and the positive potential HVDD through the transistors PT3, PT24, PT25 of the first circuit section 24b11 even in the case where the transistors PT3 and PT24 are in on state. Also, since the transistor PT3 of the first circuit section 24b11 is on, the potential of the node ND1 is held at H level. As a result, the transistor PT1 of the first circuit section 24b11 is held off.

In the second circuit section 24b12, on the other hand, the clock signal HCLK1 input to the transistor PT24 is reduced to L level, while the clock signal HCLK2 input to the transistor PT25 is raised to H level. In this way, the transistor PT24 of the second circuit section 24b12 is turned on, while turning off the transistor PT25.

In the process, according to the third embodiment, the L-level charge stored in the capacitor C2 in initial mode is supplied through the transistor PT24 of the second circuit section 24b12. At the same time, since the transistor PT3 of the second circuit section 24b12 is in off state, the potential of the node ND3 drops to L level. As a result, the transistor PT1 of the second circuit section 24b12 is turned on.

Under this condition, the transistor PT2 of the second circuit section 24b12 is in off state, and therefore the potential of the node ND4 drops to the negative potential HVSS through the transistor PT1 in on state. In this case, the potential of the node ND3 (the gate potential of the transistor PT1) drops with the decrease in the potential of the node ND4 (the source potential of the transistor PT1) in such a manner that the gate-source voltage of the transistor PT1 is maintained by the capacitor C1 of the second circuit section 24b12. Also, in the second circuit section 24b12, the transistors PT3 and PT25 are in off state, and therefore the holding voltage of the capacitor C1 (the gate-source voltage of the transistor PT1) is maintained. With the decrease in the potential of the node ND4, therefore, the transistor PT1 of the second circuit section 24b12 is normally kept on, so that the potential of the node ND4 providing an output potential drops to HVSS. As a result, the L-level output signal Dummy-SR1 is output from the second circuit section 24b12.

Incidentally, in the case where the potential of the node ND4 drops to HVSS in the second circuit section 24b12, the potential of the node ND3 is lower than HVSS. Therefore, the bias voltage applied to the transistor PT3 connected to the positive potential HVDD is higher than the potential difference between HVDD and HVSS.

Next, in the first circuit section 24b11 and the second circuit section 24b12, the clock signal HCLK1 input to the transistor PT24 rises to H level, while the clock signal HCLK2 input to the transistor PT25 drops to L level at the same time. Thus, in the first circuit section 24b11 and the second circuit section 24b12, the transistor PT24 is turned off and the transistor PT25 is turned on. Also in this case, the potential of the nodes ND1 and ND2 is maintained at H level. The nodes ND3 and ND4 are held floating at L level. As a result, the L-level output signal Dummy-SR1 of the second circuit section 24b12 is maintained.

In the process, according to the third embodiment, in the first circuit section 24b11 and the second circuit section 24b12, the L-level charge is supplied from the negative potential HVSS through the transistor PT25 and stored in the capacitor C2 during the period when the clock signal HCLK1 is at H level and the clock signal HCLK2 is at L level.

When the start signal HST input to the first circuit section 24b11 rises to H level, the transistors PT2 and PT3 of the first circuit section 24b11 are turned off. In this case, the nodes ND1 and ND2 are held floating at H level, and therefore have no effect on the other parts. Therefore, the L-level output signal Dummy-SR1 from the second circuit section 24b12 is maintained.

Next, in the first circuit section 24b11, the clock signal HCLK1 input to the transistor PT24 drops to L level while the clock signal HCLK2 input to the transistor PT25 rises to H level. As a result, the transistor PT24 of the first circuit section 24b11 is turned on while the transistor PT25 is turned off.

In the process, according to the third embodiment, the L-level charge stored in the capacitor C2 of the first circuit section 24b11 is supplied through the transistor PT24. At the same time, since the transistor PT3 of the first circuit section 24b11 is in off state, and therefore the potential of the node ND1 drops to L level. Thus, the transistor PT1 of the first circuit section 24b11 is turned on, so that the potential of the node ND2 drops to the negative potential HVSS. In this case, the potential of the node ND1 drops with the potential of the node ND2 in such a manner that the gate-source voltage of the transistor PT1 is maintained by the capacitor C1. Also, since both the transistors PT3 and PT25 are in off state, the holding voltage of the capacitor C1 (the gate-source voltage of the transistor PT1) is maintained. As a result, with the decrease in the potential of the node ND2, the transistor PT1 is normally kept on, so that the potential of the node ND2 drops to L level of HVSS. Thus, the transistors PT2 and PT3 of the second circuit section 24b12 are turned on.

The turning on of the transistor PT3 of the second circuit section 24b12 raises the potential of the node ND3 to H level, and therefore the transistor PT1 is turned off. The transistors PT1 and PT2 of the second circuit section 24b12 are prevented from turning on at the same time, so that the penetration current is suppressed from flowing between the negative potential HVSS and the positive potential HVDD through the transistors PT1 and PT2 of the second circuit section 24b12.

In the second circuit section 24b12, the clock signal HCLK1 input to the transistor PT24 drops to L level, while the clock signal HCLK2 input to the transistor PT25 rises to H level.

In the process, according to the third embodiment, the transistor PT24 of the second circuit section 24b12 is turned on, while the transistor PT25 is turned off. In this case, the turning off of the transistor PT25 suppresses the penetration current from flowing between the negative potential HVSS and the positive potential HVDD through the transistors PT3, PT24, PT25 of the second circuit section 24b12.

The transistor PT2 of the second circuit section 24b12 is turned on, while the transistor PT1 is turned off, so that the potential of the node ND4 rises to H level HVDD from HVSS. Thus, the H-level output signal Dummy-SR1 is output from the second circuit section 24b12.

As described above, according to the third embodiment, assume that in the case where the L-level start signal HST is input to the first circuit section 24b11 of the first-stage dummy shift register circuit 24b1, the L-level clock signal HCLK1 and the H-level clock signal HCLK2 are input. The L-level output signal Dummy-SR1 is output from the second circuit section 24b12. After that, the input clock signal HCLK1 rises to H level, while the clock signal HCLK2 drops to L level, after which the clock signal HCLK1 drops to L level again, while the clock signal HCLK2 rises to H level. Then, the output signal Dummy-SR1 from the second circuit section 24b12 rises to H level.

The output signal Dummy-SR1 from the second circuit section 24b12 of the first-stage dummy shift register circuit 24b1 is input to the first circuit section 24b21 of the second-stage dummy shift register circuit 24b2. In the second-stage dummy shift register circuit 24b2, assume that the H-level clock signal HCLK1 and the L-level clock signal HCLK2 are input while the L-level output signal Dummy-SR1 of the first-stage dummy shift register circuit 24b1 is input to the first circuit section 24b21. The L-level output signal Dummy-SR2 is output from the second circuit section 24b22. Further, in the first-stage shift register circuit 24a1, assume that the L-level clock signal HCLK1 and the H-level clock signal HCLK2 are input while the L-level output signal Dummy-SR2 of the second-stage dummy shift register circuit 24b2 is input to the first circuit section 24a11. The L-level output signal SR1 is output from the second circuit section 24a12.

In the second-stage shift register circuit 24a2, assume that the L-level clock signal HCLK1 and the H-level clock signal HCLK2 are input while the L-level output signal SR1 of the first-stage shift register circuit 24a1 is input to the first circuit section 24a21. The L-level output signal SR2 is output from the second circuit section 24a22. As described above, the L-level output signal from the shift register circuit in the preceding stage is input to the shift register circuit in the next stage, while the clock signals HCLK1 and HCLK2 are input to the shift register circuit of each stage, so that the L-level output signals shifted in timing are output sequentially from the shift register circuit of each stage.

The timing-shifted L-level signal is input to the transistor PT30 in each stage of the horizontal switch 3, so that the transistors PT30 of each stage are sequentially turned on. The video signal is supplied from the video signal line Video to the drain line of each stage, and therefore the drain lines of each stage are sequentially driven (scanned). Incidentally, the drain of the transistor PT30 supplied with the output signals Dummy-SR1, Dummy-SR2 and Dummy-SR3 of the dummy shift register circuits 24b1, 24b2 and 24b3, respectively, is not connected to the drain line, and therefore, even when the the transistor PT30 is turned on, the video signal is not supplied to the drain line.

Upon complete scanning of the drain lines in all the stages connected to one gate line, the next gate line is selected. After sequentially scanning the drain lines of each stage again, the next gate is selected. This operation is repeated until the end of the scanning of each stage connected to the last gate line, thereby completing the scanning of one screen.

According to the third embodiment, the provision of the transistor PT24 connected to the gate of the transistor PT1 and operated to turn on in response to the clock signal HCLK1 and the transistor PT25 connected between the transistor PT24 and the negative potential HVSS and operated to turn on in response to the clock signal HCLK2 constituting an inverted version of the clock signal HCLK1 makes it possible to turn off the transistor PT25 when the transistor PT24 is in on state while turning on the transistor PT25 when the transistor PT24 is in off state, using the clock signals HCLK1 and HCLK2. As a result, at least one of the transistors PT24 and PT25 is normally kept off. Even in the case where the transistor PT3 connected to the positive potential HVDD is in on state, therefore, the penetration current is prevented from flowing between the negative potential HVSS and the positive potential HVDD through the transistors PT3, PT24 and PT25.

According to the third embodiment, like in the first embodiment described above, the penetration current can be prevented from flowing between the positive potential HVDD and the negative potential HVSS through the transistors PT1 and PT2 by the transistor PT3 for turning off the transistor PT1 when the transistor PT2 is in on state. According to the third embodiment, therefore, the penetration current can be prevented from flowing between the positive potential HVDD and the negative potential HVSS not only through the transistors PT1 and PT2 but also through the transistors PT3, PT24 and PT25. In this way, as compared with the first embodiment, the increase in the current consumption of the liquid crystal display can be suppressed more.

Also, according to the third embodiment, two stages of dummy shift register circuits 24b1, 24b2 not connected to the drain line are arranged in the stage (operation starting side) preceding to the plurality of stages of the shift register circuits 24a1, 24a2, . . . , 24an connected to the drain line. Therefore, the shift register circuit in the second stage as counted from the operation starting side constitutes the second-stage dummy shift register circuit 24b2 not connected to the drain line. Thus, display irregularities are prevented from occurring in an area corresponding to the shift register circuit in the second stage as counted from the operation starting side. Also, the dummy shift register circuit 24b3 not connected to the drain line is arranged in the stage following the last one (shift register circuit 24an) of the plurality of stages of the shift register circuits 24a1, 24a2, . . . , 24an connected to the drain line. Thus, the last-stage shift register circuit is made up of the dummy shift register circuit 24b3 not connected to the drain line, and therefore the display irregularities are prevented from being generated in an area corresponding to the last-stage shift register circuit.

The other effects of the third embodiment are similar to those of the first embodiment.

Fourth Embodiment

With reference to FIG. 12, an example of application of the invention to an organic EL display is explained as a fourth embodiment of the invention.

In the organic EL display according to the fourth embodiment, as shown in FIG. 12, a display section 11 is arranged on a board 60. The display section 11 shown in FIG. 12 represents the configuration of one pixel. The pixels 12 arranged in matrix on the display section 11 are each configured of two p-channel transistors 12a, 12b (hereinafter referred to as the transistor 12a, 12b, respectively), an auxiliary capacitor 12c, an anode 12d, a cathode 12e opposed to the anode 12d, and an organic EL element 12f held between the anode 12d and the cathode 12e. The gate of the transistor 12a is connected to the gate line. The source of the transistor 12a is connected to the drain line. The drain of the transistor 12a is connected with the auxiliary capacitor 12c and the gate of the transistor 12b. The drain of the transistor 12b is connected to the anode 12d. The internal configuration of the H driver 4 is similar to that of the H driver 4 of the shift register circuit using the transistor shown in FIG. 2. The configuration of other parts of the organic EL display according to the fourth embodiment is similar to that of the liquid crystal display according to the first embodiment shown in FIG. 1.

According to the fourth embodiment, the above-mentioned configuration of the organic EL display can produce the same effects as the first embodiment by suppressing the increase in the current consumption of the H driver and the display irregularities of the display section.

The embodiments disclosed herein should be considered illustrative and not limitative in all aspects. The scope of this invention is indicated not by the description of the embodiments but the claims appended thereto, and includes all modifications without departing from the scope and spirit of the claims thereof.

The invention is not limited to the embodiments described above, and for example, a dummy shift register circuit may be arranged only in the first or last stage of the shift register circuit. Also, three or more stages of dummy shift register circuits may be arranged in the first stage.

The invention is not limited to the embodiments described above, and for example, a display other than the liquid crystal display and the organic EL display is applicable.

The invention is not limited to the embodiments described above, and for example, the shift register circuit according to the invention is applicable to both the H driver and the V driver. In such a case, the current consumption can be further reduced.

What is claimed is:

1. A display comprising:
a plurality of stages of shift register circuits for sequentially driving a plurality of drain lines for supplying a video signal to pixels; and
a plurality of stages of first dummy shift register circuits arranged on the operation starting side of said plurality of stages of shift register circuits and not connected to said drain line;
wherein said shift register circuits and said first dummy shift register circuits include a first circuit section having a first transistor of first conductivity type connected to a first potential, a second transistor of first conductivity type connected to a second potential, and a third transistor of first conductivity type connected between the gate of said first transistor and said second potential for turning off said first transistor when said second transistor is in on state.

2. A display according to claim 1, further comprising a second dummy shift register circuit arranged on the side opposite to the operation starting side of said plurality of stages of shift register circuits and not connected to said drain line.

3. A display according to claim 1,
wherein a start signal is input to the first stage of said plurality of stages of first dummy shift register circuits.

4. A display according to claim 1,
wherein at least said first transistor, said second transistor and said third transistor are a p-type field effect transistor.

5. A display according to claim 1,
wherein a first capacitor is connected between the gate and the source of said first transistor.

6. A display according to claim 1,
wherein said third transistor has two gate electrodes electrically connected to each other.

7. A display according to claim 1,
wherein said first transistor is turned on in response to a clock signal.

8. A display according to claim 1, further comprising a diode-connected fourth transistor connected between the gate of said first transistor and a clock signal line for supplying a clock signal.

9. A display according to claim 8,
wherein said diode-connected fourth transistor has two gate electrodes electrically connected to each other.

10. A display according to claim 1,
wherein said first circuit section further includes a fifth transistor of first conductivity type connected between the gate of said first transistor and a clock signal line for supplying a clock signal and operated to turn on in response to a signal turned on when said third transistor is in off state.

11. A display according to claim 1,
wherein said first circuit section includes a fourth transistor of first conductivity type connected to the gate of said first transistor and operated to turn on in response to a first signal, and a fifth transistor of first conductivity type connected between said fourth transistor and said first potential and operated to turn on in response to a second signal turned off when said first signal is in on state.

12. A display according to claim 11,
wherein a second capacitor is connected between the source of said first transistor and the junction point between said fourth transistor and said fifth transistor.

13. A display comprising:
a plurality of stages of shift register circuits for sequentially driving a plurality of drain lines for supplying a video signal to pixels; and
a dummy shift register circuits arranged on at least the side opposite to the operation starting side of said plurality of stages of shift register circuits and not connected to said drain line;
wherein said shift register circuits and said dummy shift register circuits include a first circuit section having a first transistor of first conductivity type connected to a first potential, a second transistor of first conductivity type connected to a second potential, and a third transistor of first conductivity type connected between the gate of said first transistor and said second potential for turning off said first transistor when said second transistor is in on state.

14. A display according to claim 13, further comprising two stages of dummy shift register circuits not connected to said drain line and arranged on the operation starting side of said plurality of stages of shift register circuits.

15. A display according to claim 13,
wherein at least said first transistor, said second transistor and said third transistor are a p-type field effect transistor.

16. A display according to claim 13,
wherein a first capacitor is connected between the gate and the source of said first transistor.

17. A display according to claim 13,
wherein said third transistor has two gate electrodes electrically connected to each other.

18. A display according to claim 13,
wherein said first transistor is turned on in response to a clock signal.

19. A display according to claim 13, further comprising a diode-connected fourth transistor connected between the gate of said first transistor and a clock signal line for supplying a clock signal.

20. A display according to claim 19,
wherein said diode-connected fourth transistor has two gate electrodes electrically connected to each other.

21. A display according to claim 13,
wherein said first circuit section further includes a fifth transistor of first conductivity type connected between the gate of said first transistor and a clock signal line for supplying a clock signal and operated to turn on in response to a signal turned on when said third transistor is in off state.

22. A display according to claim 13,
wherein said first circuit section includes a fourth transistor of first conductivity type connected to the gate of said first transistor and operated to turn on in response to a first signal, and a fifth transistor of first conductivity type connected between said fourth transistor and said first potential and operated to turn on in response to a second signal turned off when said first signal is in on state.

23. A display according to claim 22,
wherein a second capacitor is connected between the source of said first transistor and the junction point between said fourth transistor and said fifth transistor.
